(19) United States
(12) Patent Application Publication
(10) Pub. No.: US 2015/0069609 A1
(43) Pub. Date: Mar. 12, 2015

(54) 3D CHIP CRACKSTOP

(71) Applicant: International Business Machines Corporation, Armonk, NY (US)

(72) Inventors: Mukta G. Farooq, Hopewell Junction, NY (US); Erdem Kaltalioglu, Newburgh, NY (US)

(73) Assignee: International Business Machines Corporation, Armonk, NY (US)

(21) Appl. No.: 14/024,663

(22) Filed: Sep. 12, 2013

(51) Int. Cl. H01L 23/00; H01L 23/48; H01L 21/768

(52) U.S. Cl. CPC H01L 23/562; H01L 21/76898; H01L 23/481
USPC 257/741; 438/667; 257/774

(57) ABSTRACT

Embodiments of the present invention provide a crackstop and seal ring for 3D chip stacked wafers. A continuous through-silicon trench (TST) spans multiple wafers of a 3D chip stacked wafer, and forms a closed shape around a functional circuit or die, protecting the chip during subsequent fabrication such as dicing and packaging.

### FIELD OF THE INVENTION

The present invention relates generally to semiconductor fabrication, and more particularly, to a crackstop for a 3D stacked chip.

### BACKGROUND OF THE INVENTION

The density of integrated circuit chips has been increasing at a rapid rate over the past decade, and this need for increased density will continue for applications such as mobile phones, digital cameras, global positioning systems (GPS), and computers. In addition, there is a demand for increased chip packaging density to increase performance, reduce space, and provide higher functionality per unit volume needed for applications such as space-based electronic systems, miniaturized electronics for weaponry and surveillance, and hand-held electronics systems. One solution to the demand for increased density is to package the chips closer together, so that the effective density per unit volume increases. The densest packaging of chips is to stack them one on top of another into a single three dimensional (3D) unit or cube. Such a multi-level chip assembly which is also known as a 3D chip, allows a plurality of flash memory chips or a CPU to be stacked with at least one memory chip and other types of chips. With the large number of integrated circuits being produced today, product yield becomes significant. It is therefore desirable to have improvements in the fabrication of 3D chips that can improve product yield.

### SUMMARY OF THE INVENTION

In a first aspect, embodiments of the present invention provide a method of forming a crackstop on a 3D semiconductor structure, the 3D semiconductor structure comprising a first wafer having a substrate and a back-end-of-line (BEOL) region, a second wafer having a substrate and a back-end-of-line (BEOL) region, wherein the second wafer is disposed on the first wafer, the method comprising: forming a through-silicon-trench (TST) in a closed shape around a circuit formed in the 3D semiconductor structure, wherein the TST traverses the second wafer, and extends through the BEOL region of the first wafer, and into the substrate of the first wafer.

In a second aspect, embodiments of the present invention provide a semiconductor structure comprising: a first wafer having a substrate and a back-end-of-line (BEOL) region; a second wafer having a substrate and a back-end-of-line (BEOL) region, wherein the second wafer is disposed on the first wafer; and a through-silicon-trench (TST) formed in a closed shape around a die that is formed in the semiconductor structure, wherein the TST traverses the second wafer, and extends through the BEOL region of the first wafer, and into the substrate of the first wafer.

In a third aspect, embodiments of the present invention provide a semiconductor structure comprising: a first wafer having a substrate and a back-end-of-line (BEOL) region; a second wafer having a substrate and a back-end-of-line (BEOL) region, wherein the second wafer is disposed on the first wafer; a third wafer having a substrate and a back-end-of-line (BEOL) region, wherein the third wafer is disposed on the second wafer; and a first through-silicon-trench (TST) formed in a closed shape around a circuit that is formed in the semiconductor structure, wherein the first TST traverses the third wafer and the second wafer, and extends through the BEOL region of the first wafer, and into the substrate of the first wafer.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG). Furthermore, for clarity, some reference numbers may be omitted in certain drawings.

FIG. 1 is a semiconductor structure at a starting point for embodiments of the present invention.

FIG. 2 is a semiconductor structure after a subsequent process step of depositing a photoresist layer.

FIG. 3 is a semiconductor structure after a subsequent process step of patterning the photoresist layer.

FIG. 4 is a semiconductor structure after a subsequent process step of etching through-silicon trench features.

FIG. 5 is a semiconductor structure after a subsequent process step of forming an oxide liner in the through-silicon trenches.

FIG. 6 is a semiconductor structure after a subsequent process step of depositing a fill metal in the through-silicon trenches.

FIG. 7 is a semiconductor structure after a subsequent process step of planarizing the structure.

FIG. 8A is a top-down view of the semiconductor structure of FIG. 7.

FIG. 8B is a top-down view of a semiconductor structure in accordance with alternative embodiments of the present invention.

FIG. 8C is a top-down view of a semiconductor structure in accordance with alternative embodiments of the present invention.

FIG. 9 is a semiconductor structure in accordance with alternative embodiments of the present invention.

FIG. 10 is a flowchart indicating process steps for embodiments of the present invention.

### DETAILED DESCRIPTION

Embodiments of the present invention provide a crackstop and seal ring for 3D chip stacked wafers. A continuous through-silicon trench (TST) spans multiple wafers of a 3D chip stacked wafer, and forms a closed shape around a functional circuit or die, protecting the chip during subsequent fabrication such as dicing and packaging. Overall, the crackstop provides additional mechanical robustness for the 3D chip.

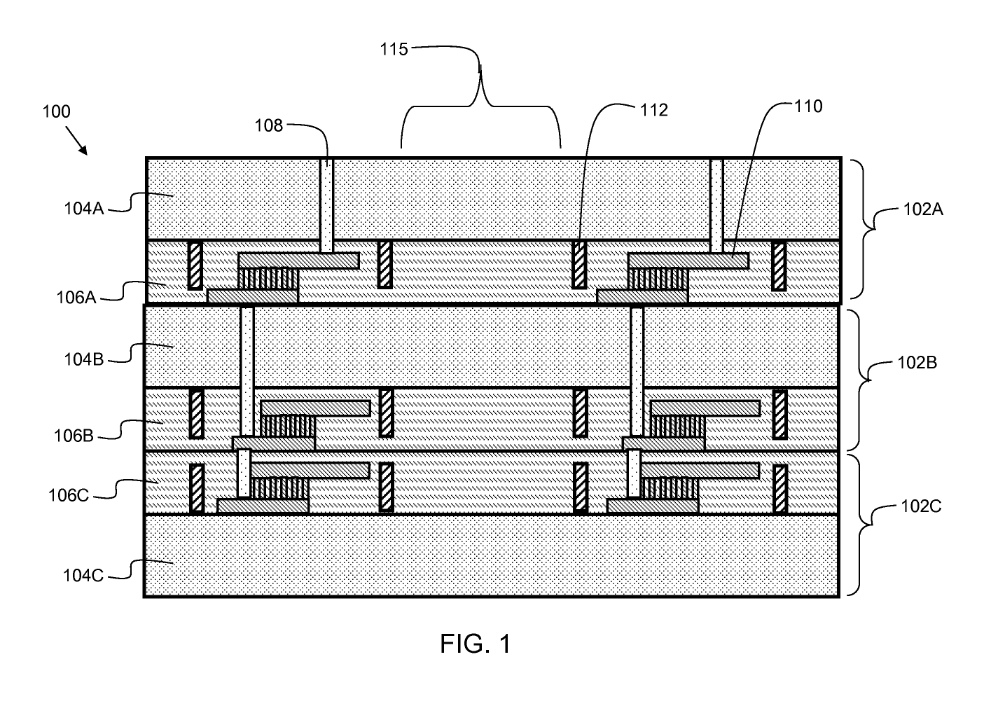

FIG. 1 is a semiconductor structure 100 at a starting point for embodiments of the present invention. Structure 100 comprises a plurality of wafers stacked upon each other, which are collectively referred to as a “3D semiconductor structure.” Structure 100 comprises wafer 102A, wafer 102B, and wafer 102C. Wafer 102A comprises semiconductor substrate 104A, and back end of line (BEOL) region 106A. Wafer 102B comprises semiconductor substrate 104B, and BEOL region 106B. Wafer 102C comprises semiconductor substrate 104C, and BEOL region 106C. The BEOL region may contain one or more metallization layers, via layers, and dielectric layers. Together, the metallization layers, via layers, and dielectric layers enable connectivity to various devices formed in the substrate region, such as transistors, diodes, and the like. Reference 110 refers to a generic BEOL structure representative of a functional circuit that is part of a chip or die. Disposed on each side of BEOL structure 110 is a BEOL crackstop, indicated generally as 112. BEOL crackstops 112 define a dicing channel 115 which demarks a region where the structure 100 may be cut to form individual chips. A through silicon via (TSV), indicated generally as 108, is used to connect the BEOL structure on one wafer to the BEOL structure of another wafer. TSVs are formed from holes in the wafer that are filled with a conductor such as copper or tungsten. TSVs are an example of a way to form connections between multiple wafers in a 3D stacked chip, but the chips may be connected by other means instead of, or in addition to TSVs. In some cases, the individual wafers may be stacked in a similar orientation, such that a BEOL region is against an adjacent substrate, as is the case with wafers 102A and 102B. In other cases, the individual wafers may be stacked in an opposing orientation, such that a BEOL region is against an adjacent BEOL region, as is the case with wafers 102B and 102C.

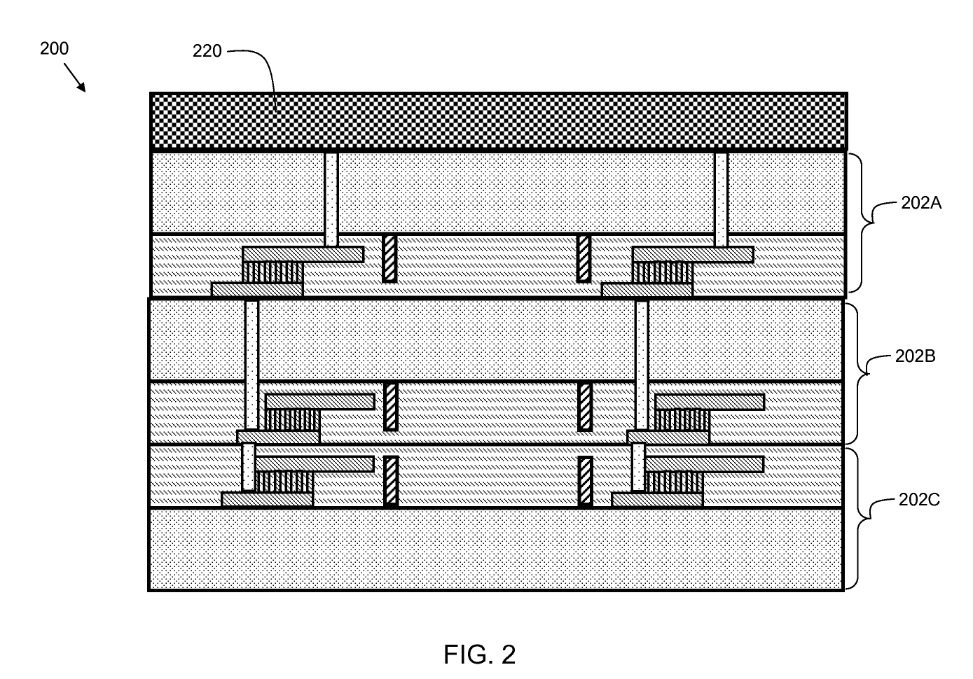

FIG. 2 is a semiconductor structure 200 after a subsequent process step of depositing a photoresist layer 220. As stated previously, similar elements may be referred to by similar numbers in various figures (FIGs) of the drawing, in which case typically the last two significant digits may be the same. For example, wafer 202A of FIG. 2 is similar to wafer 102A of FIG. 1. As an alternative embodiment, a hardmask may be used in place of photoresist layer 220, or alternatively, a combination of hardmask and photoresist may be used.

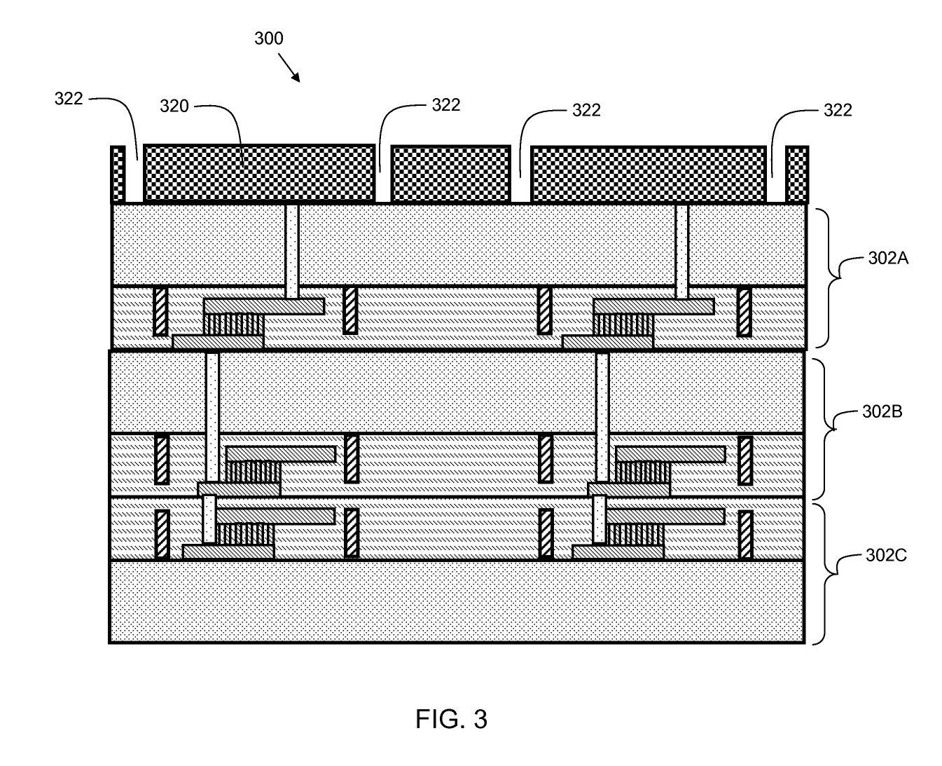

FIG. 3 is a semiconductor structure 300 after a subsequent process step of patterning the photoresist layer 320 to form cavities 322.

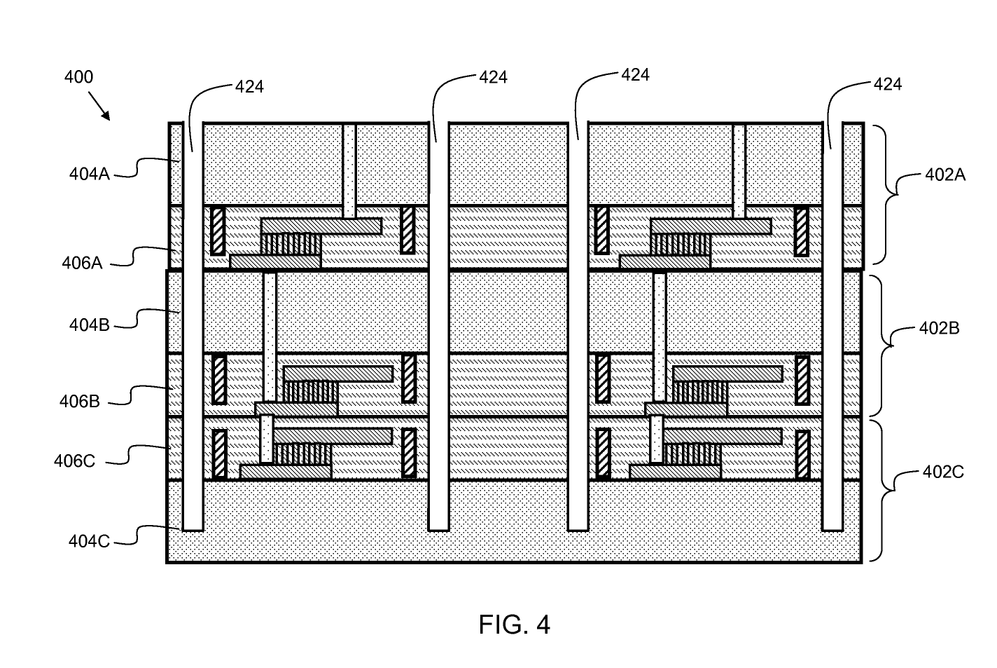

FIG. 4 is a semiconductor structure 400 after a subsequent process step of etching through-silicon trench cavities 424 and removing the photoresist layer (compare with 320 of FIG. 3). In embodiments, the through-silicon trench (TST) cavities may be formed with a deep reactive ion etch (DRIE) process. The TST cavities 424 extend through the substrate 404A and BEOL region 406A of wafer 402A and into substrate 404B and BEOL region 406B of wafer 402B. The TST cavities may further extend into substrate 404C and BEOL region 406C of wafer 402C.

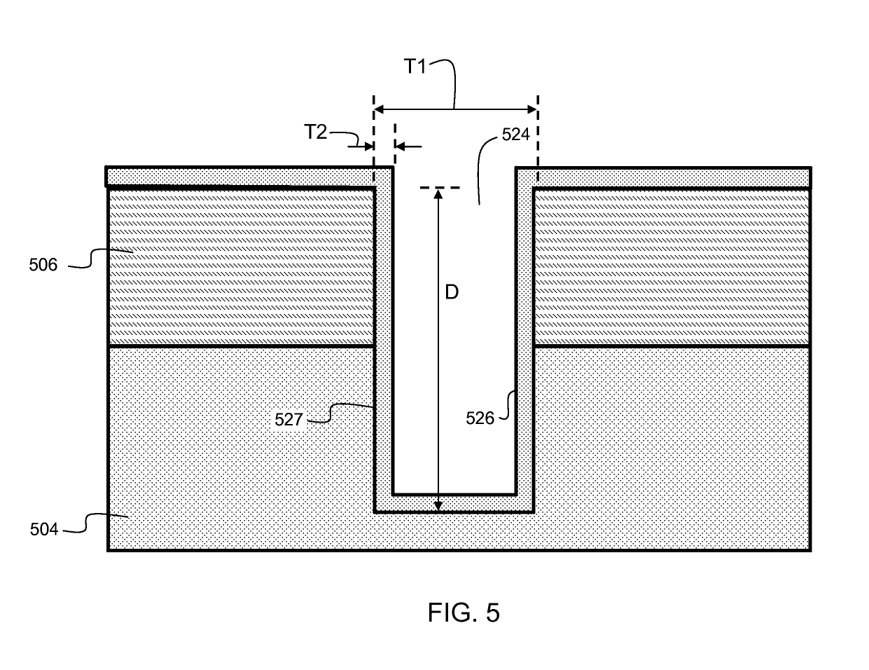

FIG. 5 shows a detailed view of a TST cavity 524 (similar to TST cavities 424 of FIG. 4) after a subsequent process step of forming an insulating liner 526 on an interior surface 527 of the TST cavity 524. In embodiments, an atomic layer deposition (ALD) or chemical vapor deposition (CVD) process is used to deposit liner 526, and hence, the liner 526 may also be deposited on the top surface as shown in FIG. 5. In embodiments, the TST cavity 524 has a width T1 that ranges from about 7 micrometers to about 30 micrometers. In other embodiments, the TST cavity 524 has a width T1 that ranges from about 10 micrometers to about 25 micrometers. In embodiments, the insulating liner 526 may be comprised of an oxide, such as silicon oxide, and may be formed by a chemical vapor deposition process. In embodiments, the insulating liner 526 has a thickness T2 ranging from about 50 nanometers to about 250 nanometers. In embodiments, the TST cavity 524 has a depth ranging from about 30 micrometers to about 1000 micrometers. In some embodiments, the aspect ratio (ratio of width T1 to depth D) ranges from about 1:10 to about 1:40.

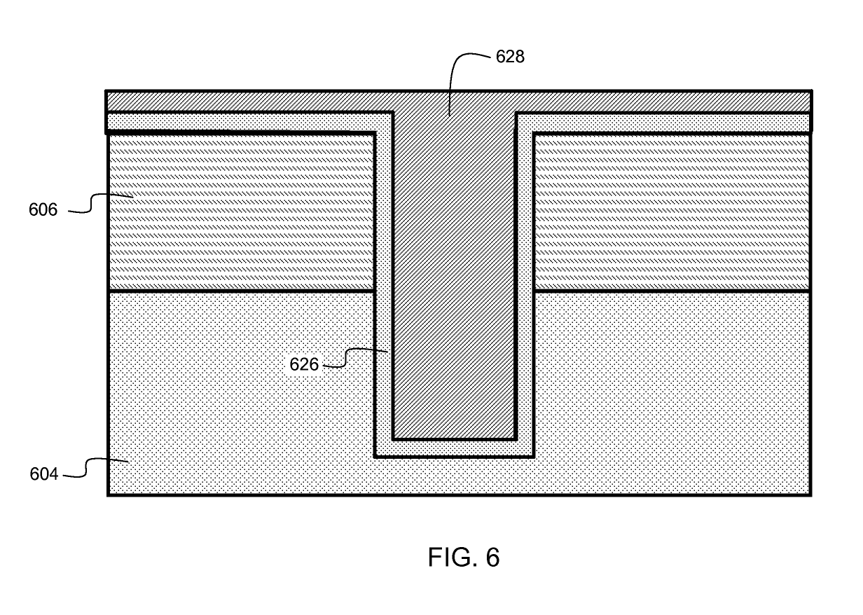

FIG. 6 shows a detailed view of a TST cavity after a subsequent process step of depositing a fill metal 628 in the TST cavity. In embodiments, the fill metal may be comprised of copper or tungsten. The oxide liner 626 is an insulator. Disposed on oxide liner 626 may typically be a thin diffusion barrier layer (not shown) such as TaN or TiN, followed by an adhesion layer such as Ta or Ti, which is followed by the copper or tungsten fill metal 628. The TaN/Ta or TiN/Ti or other diffusion barrier serves to prevent diffusion of the fill metal 628 during subsequent processing.

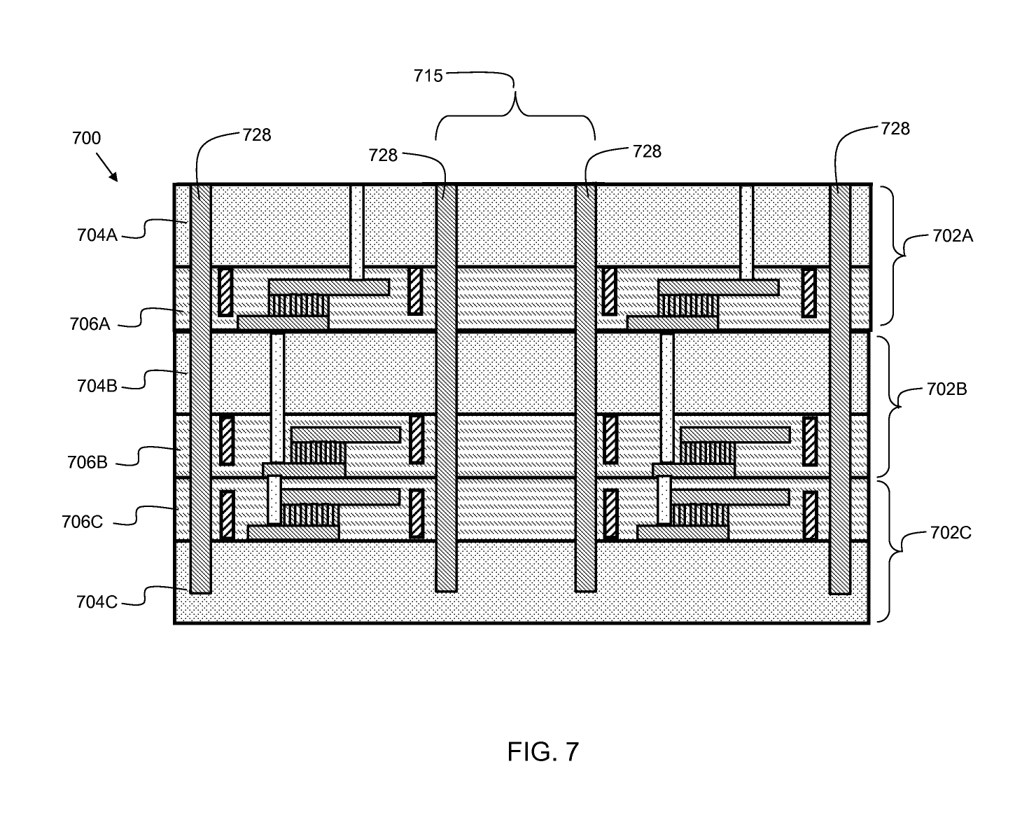

FIG. 7 is a semiconductor structure 700 after a subsequent process step of planarizing the structure, resulting in filled TST structures 728. The liner (628 of FIG. 6) under the metal fill may also be removed by the planarization step as shown in FIG. 7. Alternatively, the liner may remain on the top surface to benefit possible subsequent processes or just as added passivation. TST structures 728 serve as a 3D chip crackstop and seal ring. When the structure 700 is cut along dicing channel 715 to form individual 3D chips, there is a chance that cracks within the wafer or an interlayer dielectric can form. While the individual wafers have BEOL crackstops for a particular BEOL region (e.g. 112 of FIG. 1), the TST structures 728 provide a crackstop that spans multiple wafers to provide additional protection for a 3D structure such as structure 700.

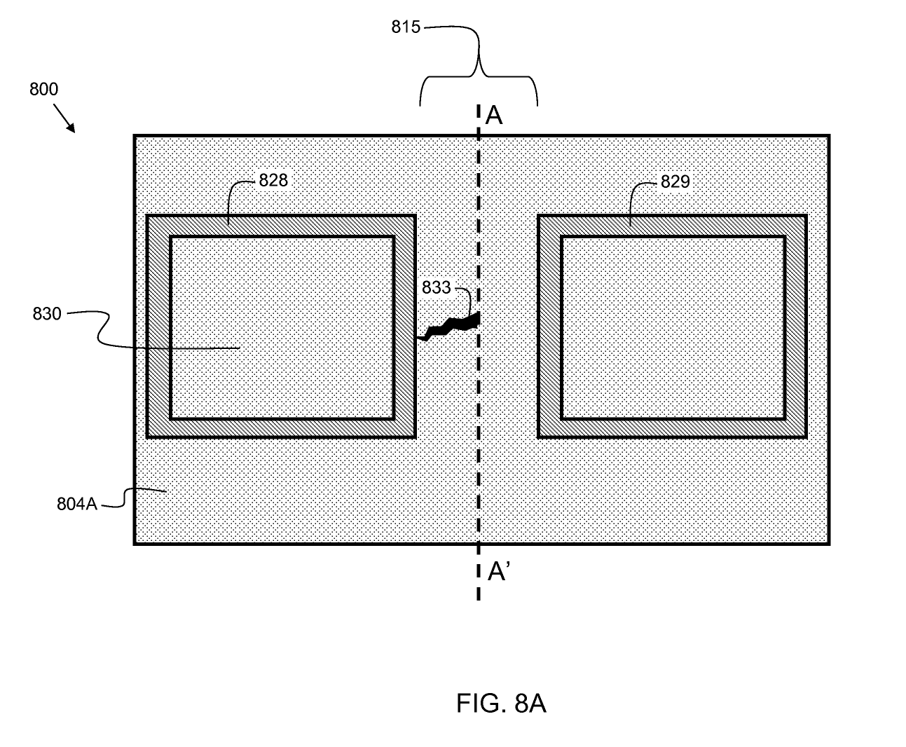

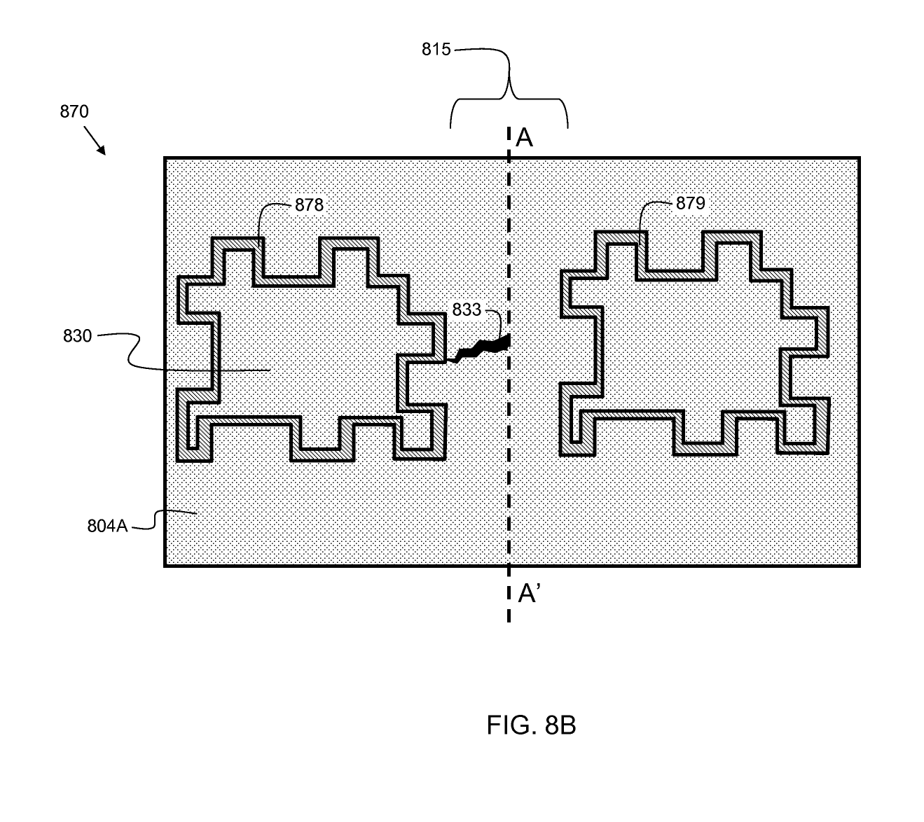

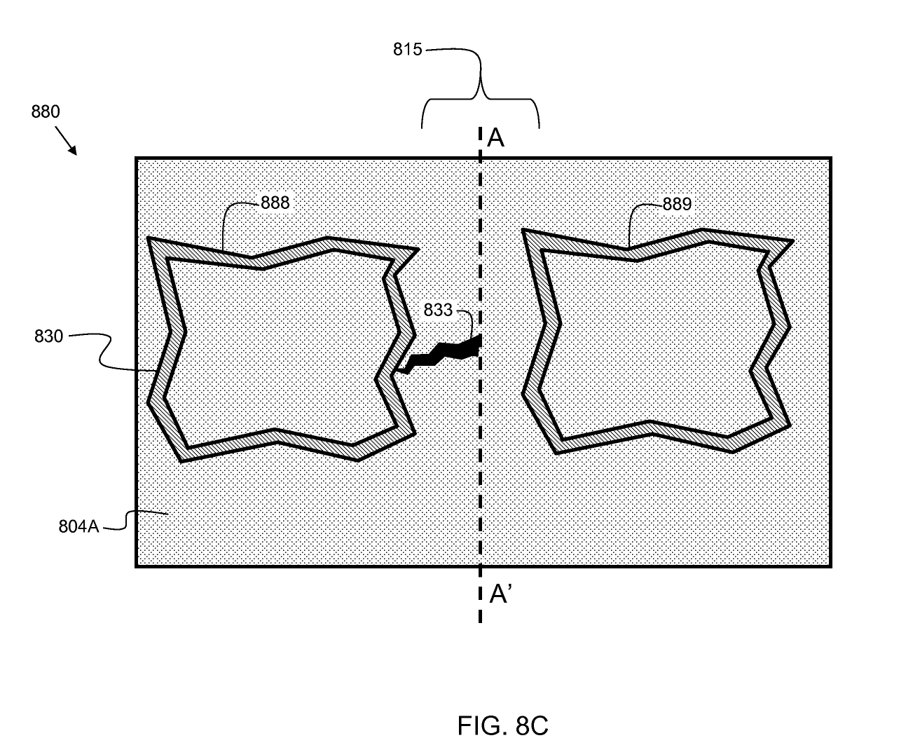

FIG. 8A is a top-down view of a semiconductor structure 800 similar to that of FIG. 7. As shown in FIG. 8A, two 3D crackstops, indicated as reference 828 and 829 are shown. The crackstops 828, 829 form a closed shape around an interior region 830 of the structure 800, where interior region 830 contains a circuit. During the fabrication process, the structure 800 is cut along line A-A′, within dicing channel 815. A crack 833 that may form as a result of the cutting is prevented from propagating into the interior region 830 by crackstop 828. Thus, the yield of 3D chips can be improved by embodiments of the present invention.

FIG. 8B is a top-down view of a semiconductor structure 870 in accordance with alternative embodiments of the present invention. As shown in FIG. 8B, two 3D crackstops, indicated as reference 878 and 879 are shown. The crackstops 878, 879 form a closed shape around an interior region 830 of the structure 870, where interior region 830 contains a circuit. The crackstops 878 and 879 are serpentine, and have a plurality of right angle turns on each side. In some embodiments, the crackstops 878 and 879 may have a non-uniform shape, and the shape may be dependent on the shape of the circuit being protected by the crackstops. A crack 833 that may form as a result of the cutting is prevented from propagating into the interior region 830 by crackstop 878.

FIG. 8C is a top-down view of a semiconductor structure 880 in accordance with alternative embodiments of the present invention. As shown in FIG. 8C, two 3D crackstops, indicated as reference 888 and 889 are shown. The crackstops 888, 889 form a closed shape around an interior region 830 of the structure 880, where interior region 830 contains a circuit. The crackstops 888 and 889 are zigzag, and have a plurality of obtuse angle turns on each side. In some embodiments, the crackstops 888 and 889 may have a non-uniform shape, and the shape may be dependent on the shape of the circuit being protected by the crackstops. A crack 833 that may form as a result of the cutting is prevented from propagating into the interior region 830 by crackstop 888.

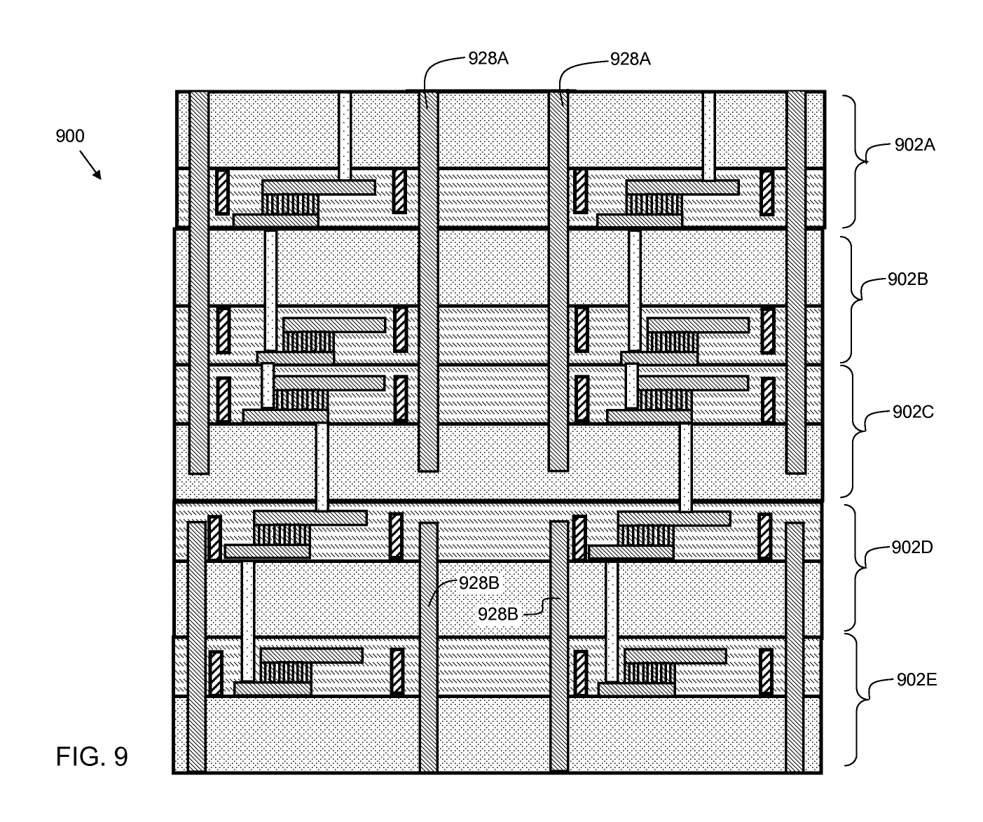

FIG. 9 is a semiconductor structure 900 in accordance with alternative embodiments of the present invention. In this embodiment, five wafers (902A, 902B, 902C, 902D, and 902E) are stacked on one another to form 3D structure 900. As the number of wafers used in a 3D structure increases, it may not be practical to form a single TST cavity that spans all the wafers in the structure. In this embodiment, multiple TST structures are formed. A first set of TST structures 928A form a 3D crackstop through wafers 902A, 902B, and 902C. A second set of TST structures 928B form a crackstop through wafers 902D and 902E. For fabrication of structure 900, wafers 902A, 902B, and 902C may be stacked on one another to form a first 3D sub-structure, and TST structures 928A formed therethrough as previously described. Separately, wafers 902D and 902E may be stacked on one another to form a second 3D sub-structure, and TST structures 928B formed therethrough as previously described. The first 3D sub-structure (comprising wafers 902A, 902B, and 902C) is then stacked onto the second 3D sub-structure (comprising wafers 902D and 902E) to form the complete 3D semiconductor structure 900. This process is extendable for any number of levels. Hence, with additional wafers in the structure, a third set of TST structures may be used, and so on.

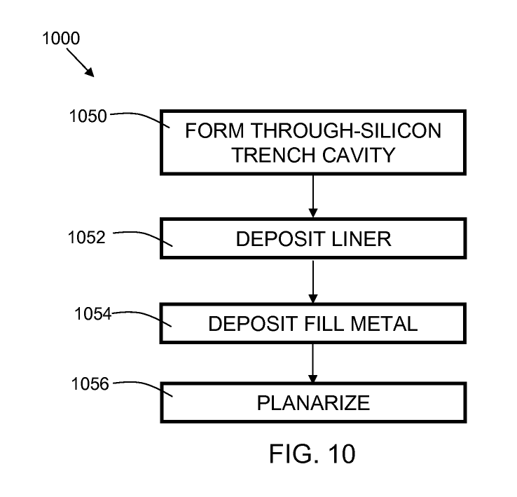

FIG. 10 is a flowchart 1000 indicating process steps for embodiments of the present invention. In process step 1050, through-silicon trench cavities are formed. In process step 1052, a liner is deposited on an interior surface of the through-silicon trench cavities, and may also be deposited on the top surface. The liner may include an oxide, such as silicon oxide. Other materials may be used instead of, or in addition to, silicon oxide. In some embodiments a barrier metal comprising tantalum, titanium, or an alloy thereof may also be used along with the oxide to form the liner. As stated previously, the materials used to line the TSV may include a diffusion barrier layer such as TaN or TiN, followed by an adhesion layer such as Ta or Ti, which is followed by the copper or tungsten metal fill. The TaN/Ta or TiN/Ti or other diffusion barrier, and serves to prevent diffusion of the fill metal during subsequent processing. In process step 1054, a fill metal is deposited. In embodiments, the fill metal may include, but is not limited to, copper, aluminum, or tungsten or other metal alloys. In process step 1056, the structure is planarized to remove excess fill metal. The planarization may be performed using a chemical mechanical polish (CMP) process.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

1. A method of forming a crackstop on a 3D semiconductor structure, the 3D semiconductor structure comprising a first wafer having a substrate and a back-end-of-line (BEOL) region, a second wafer having a substrate and a back-end-of-line (BEOL) region, wherein the second wafer is disposed on the first wafer, the method comprising:
forming a through-silicon-trench (TST) in a closed shape around a circuit formed in the 3D semiconductor structure, wherein the TST traverses the second wafer, and extends through the BEOL region of the first wafer, and partially into the substrate of the first wafer.

2. The method of claim 1, wherein forming a TST comprises forming a TST having an aspect ratio ranging from about 1:10 to about 1:40.

3. The method of claim 1, wherein forming a TST comprises forming a TST having a width ranging from about 7 micrometers to about 30 micrometers.

4. The method of claim 1, wherein forming a TST comprises forming a TST having a depth ranging from about 30 micrometers to about 1000 micrometers.

5. The method of claim 1, wherein forming a TST comprises performing a deep reactive ion etch.

6. The method of claim 5, further comprising forming an oxide liner on interior surfaces of the TST.

7. The method of claim 6, further comprising filling the TST with a metal.

8. The method of claim 7, wherein filling the TST with a metal comprises filling the TST with copper.

9. The method of claim 7, wherein filling the TST with a metal comprises filling the TST with tungsten.

10. The method of claim 7, further comprising planarizing the metal.

11. The method of claim 10, wherein planarizing the metal is performed via a chemical mechanical polish process.

12. A semiconductor structure comprising:
a first wafer having a substrate and a back-end-of-line (BEOL) region;
a second wafer having a substrate and a back-end-of-line (BEOL) region, wherein the second wafer is disposed on the first wafer; and
a through-silicon-trench (TST) formed in a closed shape around a die that is formed in the semiconductor structure, wherein the TST traverses the second wafer, and extends through the BEOL region of the first wafer, and partially into the substrate of the first wafer.

13. The semiconductor structure of claim 12, wherein the TST is formed in a serpentine shape.

14. The semiconductor structure of claim 12, wherein the TST is formed in a zigzag shape.

15. The semiconductor structure of claim 12, wherein the TST has a depth ranging from about 30 micrometers to about 1000 micrometers.

16. The semiconductor structure of claim 12, further comprising an oxide liner disposed on interior surfaces of the TST.

17. The semiconductor structure of claim 12, further comprising a metal fill material disposed within the TST.

18. The semiconductor structure of claim 17, wherein the metal fill material comprises copper.

19. A semiconductor structure comprising:
a first wafer having a substrate and a back-end-of-line (BEOL) region;
a second wafer having a substrate and a back-end-of-line (BEOL) region, wherein the second wafer is disposed on the first wafer;
a third wafer having a substrate and a back-end-of-line (BEOL) region, wherein the third wafer is disposed on the second wafer; and
a first through-silicon-trench (TST) formed in a closed shape around a circuit that is formed in the semiconductor structure, wherein the first TST traverses the third wafer and the second wafer, and extends through the BEOL region of the first wafer, and partially into the substrate of the first wafer.

20. The semiconductor structure of claim 19, wherein the first wafer, second wafer, and third wafer comprise a first 3D substructure, and further comprising a second 3D sub-structure, wherein the second 3D sub-structure comprises:
a fourth wafer having a substrate and a back-end-of-line (BEOL) region, wherein the fourth wafer is disposed on the third wafer;
a fifth wafer having a substrate and a back-end-of-line (BEOL) region, wherein the fifth wafer is disposed on the fourth wafer; and
a second through-silicon-trench (TST) formed in a closed shape around a die that is formed in the semiconductor structure, wherein the second TST traverses the fifth wafer, and extends into the fourth wafer.
